(19) United States
(12) Patent Application Publication
(10) Pub. No.: US 2004/0067627 A1
(43) Pub. Date: Apr. 8, 2004

(54) Dry lithograpy method and method of forming gate pattern using the same

(76) Inventors: Seong Jae Lee, Daejon-Shi (KR); Kyoung Wan Park, Daejon-Shi (KR); Won Ju Cho, Daejon-Shi (KR); Moon Jang Gyu, Daejon-Shi (KR); Woo Seok Cheong, Daejon-Shi (KR)

Correspondence Address: JACOBSON HOLMAN PLLC, 400 SEVENTH STREET N.W., SUITE 600, WASHINGTON, DC, 20004, US

(21) Appl. No.: 10/329,545

(22) Filed: Dec. 27, 2002

(30) Foreign Application Priority Data
Oct. 7, 2002 (KR) 2002-61073

(51) Int. Cl. H01L 21/3205; H01L 21/4763

(52) U.S. Cl. 438/585; 438/949

(57) ABSTRACT

The present invention relates to a resistless dry lithography method and a method of forming a gate pattern using the same. The present invention utilizes the phenomena of altering the susceptibility to dry etching of a portion of Si layer exposed to the energetic electron beam. The dry lithography method comprises the steps of preparing a pattern-transferring object of silicon, exposing an electron beam to a desired portion of the pattern-transferring object, and performing reactive ion etch process to selectively etch the unexposed portion, thereby leaving the exposed portion of the pattern-transferring object. The present invention is an all-dry process and the entire lithography processes can be performed on one cluster equipment in a controlled environment, eliminating human handling of wafers and exposure to atmospheric environment to minimize contaminations during the process.

### BACKGROUND OF THE INVENTION

1. Field of the Invention

The invention relates generally to a dry lithography method and a method of forming a gate pattern using the same, and more specifically a resistless dry lithography method and the method of forming a gate pattern without wet processes using the same.

2. Description of the Prior Art

The semiconductor industry has led to a remarkable advancement in miniature technologies of integrated circuits. The integrated circuits typically employ tens of million transistors and multiple levels of device interconnections fabricated in a semiconductor wafer. Various device layers are sequentially formed on a semiconductor wafer by multiple processes including the lithography process for patterning. It is known to a skilled in the art that a current lithography technique can fabricate about 0.1 micron (100 nm)-sized devices, but it is not sufficient to manufacture devices smaller than 50 nm. First of all, the fabrication of such ultra-small scale electronic devices require more efficient high-resolution lithography tool and subsequent patterning processes without wet processes in order to minimize contamination sources.

A “lithography” process means a process of creating a patterned mask on underlying region such as a surface of a semiconductor wafer so that the subsequent patterning processes may be performed. The subsequent patterning processes may include a deposition process, implant doping process, plasma etching process, or the like. Conventionally, the pattern is transferred from a masked pattern to the underlying region (i.e. pattern-transferring object) using photoresist and an optical lithography exposure tools (for example, stepper).

FIG. 1 is a flow diagram of conventional lithography process.

As shown in FIG. 1, a semiconductor substrate (a pattern-transferring object) is prepared S10. A photoresist layer is spun on with a wet process S20 and then a pre-bake process is performed to drive out the solvent and solidify the photoresist layer S30. Next, an exposure process is performed S40 and a wet develop process remove a selected portion of photoresist layer S50 and then a post-bake process may be performed S60. Thereafter, the pattern is transferred to the underlying region (substrate) typically with a plasma etch process S70. Finally, the photoresist is removed using a wet or plasma strip process S80.

A problem or limitation with the conventional lithography process is that wet liquid-based processes are used for depositing the photoresist layer and for pattern development and so on. For these reasons, the wafer is exposed to atmosphere and liquid chemicals repeatedly throughout the patterning process flow. These repeated exposures could introduce various contaminants on the wafer surface. Furthermore, the wet chemicals themselves including the photoresist may leave various metallic and organic contaminants on the surface, resulting in device performance and reliability degradation.

In the meantime, the conventional lithography process employs combinations of various process steps such as a spin-coating process, pre/post-baking process, developing process and a removal process of the photoresist and the entire lithography process is too complicated to apply to fabricate patterns smaller than 50 nm.

Therefore it is very important to develop an alternative lithography technique with simple process steps excluding wet chemicals.

### SUMMARY OF THE INVENTION

An object of the present invention is therefore to overcome the above-described drawbacks of the prior art.

Another object of the invention is to provide a dry lithography method capable of substituting the conventional lithography method without a need for the wet process.

Another object of the invention is to provide a dry lithography method capable of substituting the conventional lithography method with a reduced number of process steps.

Another object of the present invention is to provide a dry lithography method and a method of forming a gate pattern using the dry lithography method capable of substituting the conventional lithography method without a need for the wet process.

In order to accomplish the above object, a dry lithography method according to the present invention, is characterized in that it comprises the steps of preparing a pattern-transferring object of a silicon wafer, exposing an electron beam to a desired portion of the pattern-transferring object, and performing reactive ion etch process to define the pattern, where the difference in etch rates between the desired portion (to which the electron beam is exposed) and other portion (to which the electron beams is not exposed), leads to a removal of the other portion of the pattern-transferring object.

Preferably, the electron beam is accelerated with an voltage of 2˜200 kV and has 0.01˜10 Coulomb/cm² dose. The electron beam may be exposed after the pattern-transferring object is heated at a temperature of 70˜600° C. Furthermore, the exposure of the electron beam may be performed by an e-beam direct lithography or by an e-beam projection lithography tool.

The reactive ion etch process includes generating a plasma from a Cl₂ reactive gas in pressure of 3˜300 mTorr and making ions to impinge on a pattern-transferring object (silicon wafer) by applying an electric field and thereby etching selectively the desired portion of the silicon wafer, that is, the pattern-transferring object. Preferably, the reactive ion etch process is performed while the pattern-transferring object is heated at a temperature of 70˜1000° C.

The pattern-transferring object may be a silicon substrate, a silicon layer deposited on the semiconductor substrate or a silicon layer deposited on the insulating layer on the semiconductor substrate.

In order to accomplish the another object, a method of forming a gate pattern according to the present invention, is characterized in that it comprises the steps of depositing an insulating layer on a semiconductor substrate, depositing a silicon layer on the insulating layer, exposing an electron beam to a desired portion of the silicon layer, and performing reactive ion etch process using the difference in an etch rate between the desired portion of the silicon layer (to which the electron beam is exposed) and other portion of the silicon layer (to which the electron beams is not exposed), thereby removing the other portion of the silicon layer and forming a gate pattern.

### BRIEF DESCRIPTION OF THE DRAWINGS

The aforementioned aspects and other features of the present invention will be explained in the following description, taken in conjunction with the accompanying drawings, wherein:

FIG. 1 is a flowchart for explaining a conventional lithography method;

FIG. 2 is a flowchart for explaining a dry lithography method according to a preferred embodiment of the present invention; and

FIG. 3˜FIG. 5 are cross-sectional views of semiconductor devices for explaining a method of forming a gate pattern using the dry lithography method of the present invention.

### DETAILED DESCRIPTION OF PREFERRED EMBODIMENTS

The present invention will be described in detail by way of a preferred embodiment with reference to accompanying drawings, in which like reference numerals are used to identify the same or similar parts.

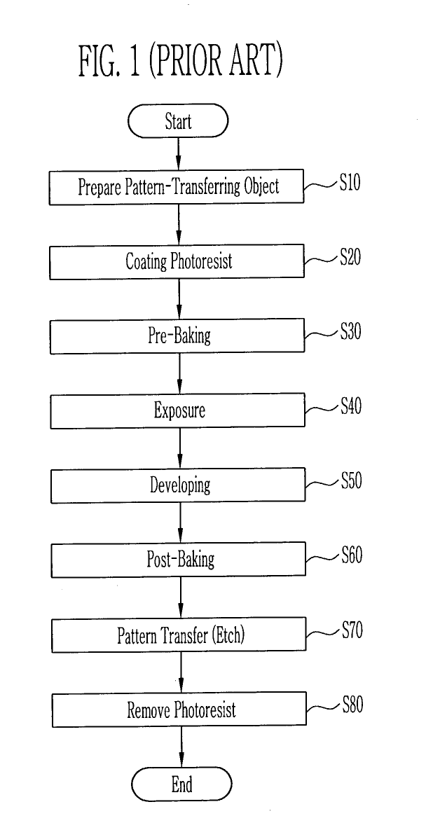

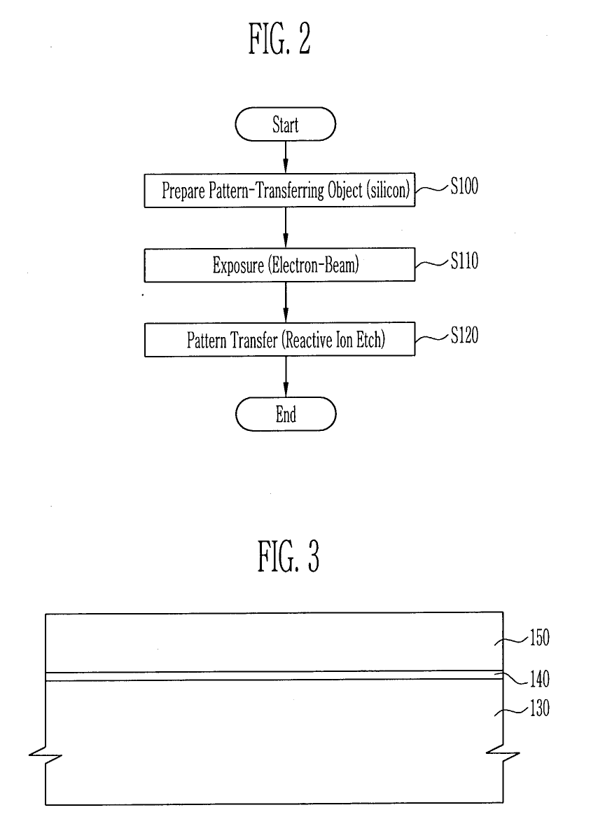

FIG. 2 is a flow diagram for explaining a dry lithography method according to a preferred embodiment of the present invention. The process steps in FIG. 2 are simplified significantly as compared to the process steps in FIG. 1.

Referring to FIG. 2, the dry lithography method of the preferred embodiments is based on a fact that, when electron-beams are exposed to a portion of the silicon layer, susceptibility of the exposed portion of silicon layer to etching is altered compared to that of unexposed portion. It means that the exposed portion and the unexposed portion have different etch rates each other with respect to a specific reactive etch process. In other words, when a portion of the silicon layer is exposed to the energetic electron beams, the exposed portion of the silicon layer has a significantly reduced susceptibility to etching as compared to other portion (unexposed portion). Thus, a subsequent reactive ion etching process can remove the silicon layer selectively.

The dry lithography method includes preparing a pattern-transferring object formed of silicon S100, exposing an electron beam to a selected region of silicon layer S110, and performing a reactive ion etching (RIE) process to transfer a desired pattern (for example, masked pattern) to the pattern-transferring object using a fact that the exposed portion have a different etch rate with the unexposed portion S120.

The pattern-transferring object may be a silicon substrate, a silicon layer deposited on the semiconductor substrate and a silicon layer deposited on an insulating layer on a semiconductor substrate.

In the exposure process, the electron beam may be used with a pattern mask or with a direct-writing method. In other words, the exposure process may use an electron-beam direct lithography tool without using the mask, or an electron-beam projection lithography (EPL) tool using the mask. Preferably, the electron beam with an acceleration voltage of 2˜200 kV (beam voltage) can be used and the electron beam dose about 0.01˜10 Coulomb/cm² can be used to this purpose. Preferably, the wafer is exposed to the electron beam after the wafer is heated at a temperature of 70˜600° C.

The process of reactive ion etch (RIE) is as follows. A plasma is generated from Cl₂ reactive gases of about 3˜300 mTorr and then ionized. It is used to remove the silicon layer selectively. Preferably, the RIE process may be performed while the semiconductor substrate is maintained or heated at a temperature of 0˜1000° C. For example, the etch rate of the unexposed portion was measured to be 30˜40 nm/min when the unexposed amorphous silicon layer was etched using a plasma of Cl₂ gas in pressure of 50 mTorr, where the amorphous silicon layer was prepared by a chemical vapor deposition (CVD) and was exposed to the energetic electron beam (accelerated with 20 kV, dose of 0.2 Coulomb/cm²). It was found that the etch rate (30˜40 nm/min) of the unexposed portion is over ten times as large as that of the exposed portion.

Since the pattern-transferring object of the present invention is formed of silicon, the unetched portion (less-etched portion, in rigorously speaking) can be used directly as a constituent element of the device. Furthermore, the dry lithography method is not based on wet-liquid based process and the entire process can be performed in a controlled environment (e.g. vacuum) since the pattern can be transferred using e-beam direct lithography system or the electron-beam projection lithography (EPL) system. Therefore, this pattern transfer process is suitable for mass production because the elimination of wet processing steps enables the use of the integrated cluster tools. The entire lithography processes can be performed on one cluster equipment in a controlled environment, eliminating human handling of wafers and exposure to atmospheric environment to minimize contaminations during the process. It increases manufacturing yields, improves reliability of the manufacturing device. For example, through the dry lithography method of the present invention, the semiconductor nano-structure can be made with a high reliability and minimum contaminants.

Furthermore, since silicon (pattern-transferring object) can be directly used as constituent elements such as a channel or a gate, the manufacturing process can be simplified.

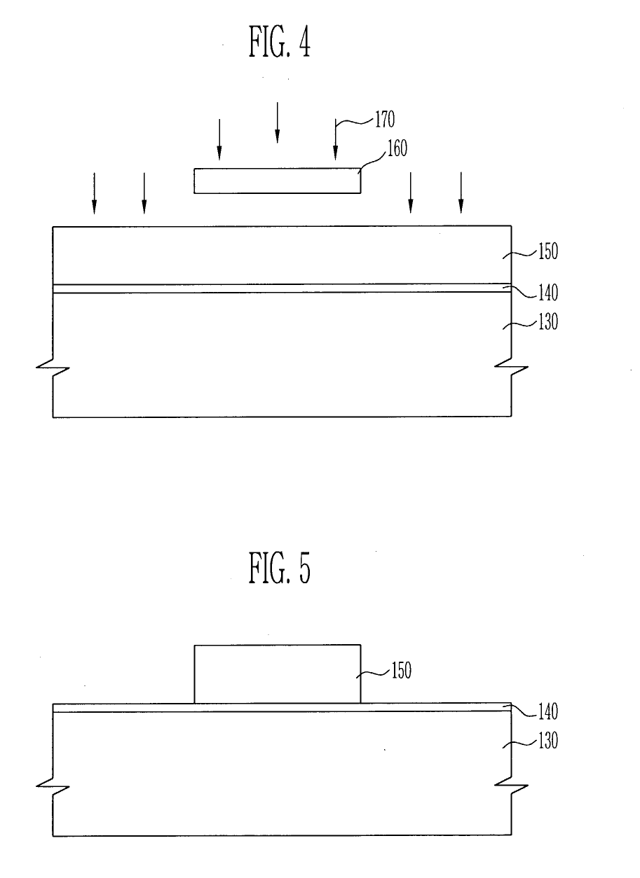

FIG. 3˜FIG. 5 shows an example of patterning a gate of semiconductor device using the dry lithography method of the present invention.

FIG. 3 shows a cross section of semiconductor wafer with an insulating layer 140 and a silicon layer 150. The insulating layer 140 may be a silicon oxide (SiO₂) layer, a silicon nitride (Si₃N₄) layer, a LaAlO₃ layer, a HfSiO₄ layer, a HfO₂ layer, a ZrO₂ layer, a ZrSiO₄ layer, an Al₂O₃ layer, or the like. In this case, preferably, the thickness of the insulating layer 140 is about 1˜100 nm.

The silicon layer 150 is deposited by, for example, chemical vapor deposition method. Upon the deposition of the silicon layer 150, the semiconductor substrate 130 can be heated at a temperature of 300˜700° C. The thickness of the silicon layer 150 can be determined depending on minimum size of the pattern. For example, the thickness of the silicon layer 150 may be about 10˜500 nm.

FIG. 4 shows that an electron beam 170 impinges on the silicon layer 150. The exposure process may be performed either through a mask 160 or without the use of a mask (direct-writing method). Preferably, the electron beam 170 is accelerated with a voltage of 2˜200 kV and the amount of dosage is about 0.01˜10 Coulomb/cm². The semiconductor substrate 130 may be exposed to the electron beam 170 after it is heated at a temperature of about 70˜600° C.

By reference to FIG. 5, the silicon layer 150 is selectively etched to perform a pattern transfer using a reactive ion etch (RIE). In other words, a plasma is generated from Cl₂ reactive gases of about 3˜300 mTorr and then ionized. It is accelerated to the silicon layer to perform selective etching. In this case, the reactive ion etch (RIE) is performed while the semiconductor substrate 130 is maintained at a temperature of 0˜600° C. The present invention can transfer the pattern using simplified and direct method compared to the conventional lithography method.

In the above explanation, it was described that one layer is positioned on the other layer. However, it should be noted that the one layer may exist right on the other layer and a third layer may be intervened between them. Further, the thickness and size of each of the layers are exaggerated for convenience of explanation and clarity.

As mentioned above, the present invention has advantageous effects that it can reduce the production time and cost by significantly reducing the process steps and additional costs related to the skipped process, compared to the conventional lithography technology. The reason is that a silicon layer is used for a patterning mask instead of the conventional photoresist film. It means that the remaining silicon structure as a mask after developing process can be used directly as elements such as a channel or a gate. Therefore, the present invention can simplify the process steps and implement a resistless lithography method.

In addition, this resistless lithography method can reduce various contaminants because the wafer is not exposed to atmosphere or wet chemicals. The present invention employs a all-dry process, excluding wet liquid-based processes completely.

The entire lithography processes can be performed on one cluster equipment in a controlled environment, eliminating human handling of wafers and exposure to atmospheric environment to minimize contaminations during the process. It increases manufacturing yields, improves reliability of the manufacturing device.

The present invention has been described with reference to a particular embodiment in connection with a particular application. Those having ordinary skill in the art and access to the teachings of the present invention will recognize additional modifications and applications within the scope thereof. It is therefore intended by the appended claims to cover any and all such applications, modifications, and embodiments within the scope of the present invention.

What is claimed is:

1. A dry lithography method, comprising the steps of:
preparing a pattern-transferring object of silicon;
exposing an electron beam to a desired portion of the pattern-transferring object; and
performing reactive ion etch process to selectively etch the unexposed portion, thereby leaving the exposed portion of the pattern-transferring object.

2. The dry lithography method as claimed in claim 1, wherein the reactive ion etch process employs a plasma generated from a Cl₂ reactive gas in pressure of 3˜300 mTorr.

3. The dry lithography method as claimed in claim 2, wherein the reactive ion etch process is performed while the pattern-transferring object is heated at a temperature of 0˜1000° C.

4. The dry lithography method as claimed in claim 1, wherein the dose of an electron beam ranges from 0.01 to 10 Coulomb/cm² and the energy of an electron beam ranges from 2 to 200 keV.

5. The dry lithography method as claimed in claim 1, wherein the pattern-transferring object is exposed to the electron beam while it is heated at a temperature of 70˜600° C.

6. The dry lithography method as claimed in claim 1, wherein the exposure of the electron beam is performed by an e-beam direct lithography tool or by an e-beam projection lithography tool.

7. The dry lithography method as claimed in claim 1, wherein the pattern-transferring object is a silicon wafer.

8. The dry lithography method as claimed in claim 1, wherein the pattern-transferring object is a silicon layer deposited on the semiconductor substrate.

9. The dry lithography method as claimed in claim 8, wherein the silicon layer is deposited by chemical vapor deposition and the deposited thickness is 1˜500 nm.

10. The dry lithography method as claimed in claim 1, wherein the pattern-transferring object is a silicon layer deposited on an insulating layer.

11. The dry lithography method as claimed in claim 10, wherein the silicon layer is deposited by CVD and the deposited thickness is 10˜500 nm.

12. The method of forming gate electrodes, comprising the steps of:
preparing a semiconductor substrate;
depositing an insulating layer on a semiconductor substrate;
depositing a silicon layer on the insulating layer;
exposing an electron beam to a desired portion of the gate electrode area on the pattern-transferring object; and
performing reactive ion etch process to selectively etch the unexposed portion, thereby leaving only the exposed portion of the gate electrodes on the pattern-transferring object.

13. The method of forming gate electrodes as claimed in claim 12, wherein the reactive ion etch process employs a plasma generated from a Cl₂ reactive gas in pressure of 3˜300 mTorr.

14. The method of forming gate electrodes as claimed in claim 13, wherein the reactive ion etch process is performed while the pattern-transferring object is heated at a temperature of 0˜1000° C.

15. The method of forming gate electrodes as claimed in claim 12, wherein the dose of an electron beam ranges from 0.01 to 10 Coulomb/cm² and the energy of an electron beam ranges from 2 to 200 keV.

16. The method of forming gate electrodes as claimed in claim 12, wherein the pattern-transferring object is exposed to the electron beam while it is heated at a temperature of 70˜600° C.

17. The method of forming gate electrodes as claimed in claim 12, wherein the exposure of the electron beam is performed by an e-beam direct lithography tool or by an e-beam projection lithography tool.

18. The method of forming gate electrodes as claimed in claim 12, wherein the insulating layer is a silicon oxide (SiO₂) layer, a silicon nitride (Si₃N₄) layer, a LaAlO₃ layer, a HfSiO₄ layer, a HfO₂ layer, a ZrO₂ layer, a ZrSiO₄ layer or an Al₂O₃ layer.

19. The method of forming gate electrodes as claimed in claim 12, wherein the thickness of insulating layer is 1˜100 nm.

20. The method of forming gate electrodes as claimed in claim 12, wherein the silicon layer is deposited by chemical vapor deposition and the deposited thickness is 10˜500 nm.
